(19) United States
(12) Patent Application Publication
(10) Pub. No.: US 2008/0094816 A1
(43) Pub. Date: Apr. 24, 2008

(54) Filter and plasma display device

(75) Inventor: Yoshiro Murayasu, Yokohama (JP)

Correspondence Address: MCDERMOTT WILL & EMERY LLP, 600 13TH STREET, N.W., WASHINGTON, DC, 20005-3096, US

(73) Assignee: FUJITSU HITACHI PLASMA DISPLAY LIMITED.

(21) Appl. No.: 11/798,369

(22) Filed: May 14, 2007

(30) Foreign Application Priority Data
Oct. 23, 2006 (JP) JP2006-287358

(51) Int. Cl. H05K 9/00

(52) U.S. Cl. 361/818

(57) ABSTRACT

A filter capable of improving its ability of shielding electromagnetic wave easily by suppressing variations in the electrical connection between the filter and a chassis without putting stress on a display panel and a plasma display device using the same are provided. In the plasma display device, a directly-attached filter has a filter contact part to be connected with the chassis, and a convex portion convexing towards the chassis is formed on the filter contact part to make secure connection with a gasket for connecting the directly-attached filter and the chassis.

### CROSS-REFERENCE TO RELATED APPLICATION

The present application claims priority from Japanese Patent Application No. JP 2006-287358 filed on Oct. 23, 2006, the content of which is hereby incorporated by reference into this application.

### TECHNICAL FIELD OF THE INVENTION

The present invention relates to a technique for a plasma display device having a display panel made of glass. More particularly, the present invention relates to a technique effectively applied to a configuration of a filter that can be attached directly on a display surface of the display panel, namely a directly-attached filter.

### BACKGROUND OF THE INVENTION

For example, in a plasma display device, a display panel made of glass thereof is held by being inserted to a chassis over the entire circumference of the chassis. On the display panel, a directly-attached filter is attached and electrically connected to the chassis. The electrical connection between the directly-attached filter and the chassis is generally made by means of inserting a gasket between a contact part of the filter and the chassis and applying pressure to make them contacted with each other, and the contact part of the filter is planarized.

### SUMMARY OF THE INVENTION

Meanwhile, according to the study by the inventor of the present invention, the following problems have been found out in the above-mentioned means for electrical connection between the directly-attached filter and the chassis.

For example, it is considered that due to distortion of display panel and chassis posed by size enlargement thereof, the electrical connection between the chassis and the filter may vary to deteriorate the ability of shielding electromagnetic wave. Further, more pressure may be applied to reduce the variations in electrical connection, but in this case, it leads putting stress on the display panel, and so it is undesirable.

Therefore, an object of the present invention is to provide a filter capable of suppressing variations in electrical connection between the filter and a chassis to improve its ability of shielding electromagnetic wave without putting stress on a display panel, and a plasma display device using the same.

The above and other objects and novel characteristics of the present invention will be apparent from the description of this specification and the accompanying drawings.

The typical ones of the inventions disclosed in this application will be briefly described as follows.

The present invention is applied to a directly-attached filter to be attached on a display panel and a display device using the same, and it includes the following features.

More specifically, the present invention includes a configuration where convex portions convexing towards a chassis are formed on a contact part of the directly-attached filter to be securely connected with gaskets for connecting the filter and the chassis.

The effects obtained by typical aspects of the present invention will be briefly described below.

According to the present invention, it is possible to improve an ability of shielding electromagnetic wave easily by suppressing variations in electrical connection between a filter and a chassis without putting stress on a display panel.

### BRIEF DESCRIPTIONS OF THE DRAWINGS

FIG. 1 is a cross-sectional diagram schematically showing a plasma display device according to an embodiment of the present invention;

FIG. 2A is a plan view showing outer appearance of a directly-attached filter of the plasma display device according to the embodiment of the present invention;

FIG. 2B is an enlarged plan view showing a filter contact part of the plasma display device according to the embodiment of the present invention;

FIG. 2C is an enlarged cross-sectional view of the filter contact part of the plasma display device according to the embodiment of the present invention; and

FIG. 3 is a cross-sectional diagram schematically showing the plasma display device having a chassis with convex portions according to the embodiment of the present invention.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

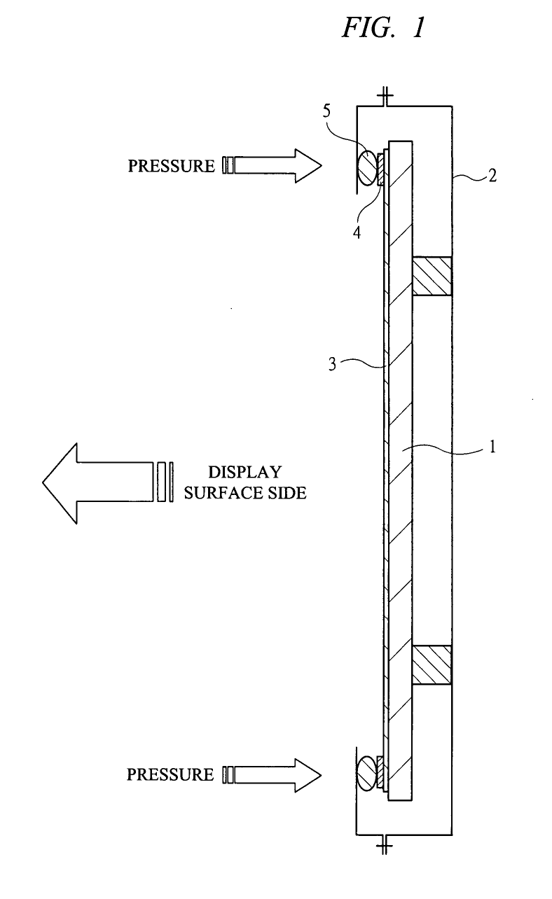

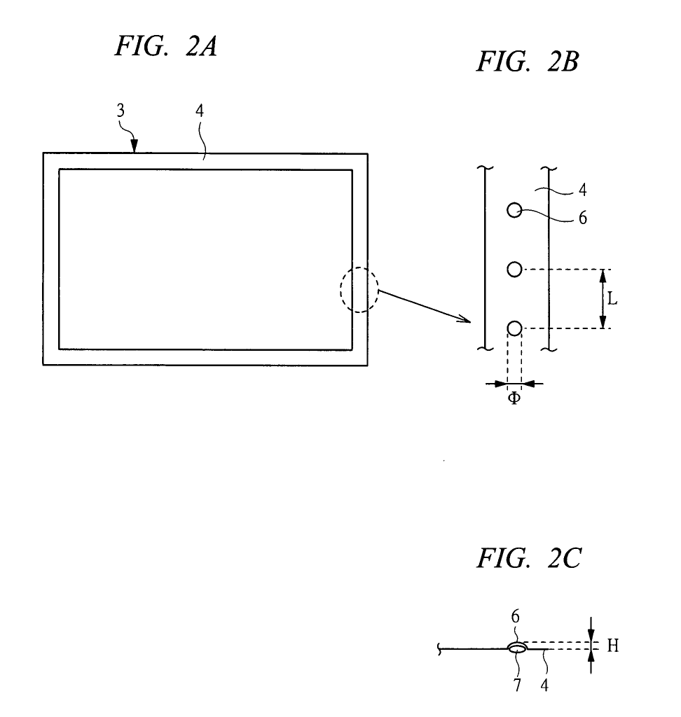

FIG. 1 is a cross-sectional diagram schematically showing a plasma display device according to an embodiment of the present invention. In FIG. 2, FIG. 2A is a plan view showing an outer appearance of the directly-attached filter, FIG. 2B is an enlarged plan view showing a contact part of the filter, and FIG. 2C is an enlarged cross-sectional view showing the contact part of the filter for describing a directly-attached filter.

As shown in FIG. 1, the plasma display device comprises: a display panel 1 made of glass; a chassis 2 holding the display panel 1 inserted to the entire circumference thereof; and a directly-attached filter 3 attached on the display panel 1.

In the plasma display device, an electrical connection between the directly-attached filter 3 and the chassis 2 is made by inserting a gasket 5 between a filter contact part 4 formed on the directly-attached filter 3 and the chassis 2, and putting pressure to make them contacted with each other.

As shown in FIG. 2, the directly-attached filter 3 has a filter contact part 4 formed around its outer circumference to make the electrical connection with the chassis. The filter contact part 4 has convex portions 6 convexing towards the chassis 2 formed all around the entire circumference thereof. By the convex portions 6 formed on the directly-attached filter 3, it is possible to make a secure connection with the gasket 5 for making connection with the chassis 2.

On a rear side of the convex portion 6 of the directly-attached filter 3, a strengthening agent 7 is applied. As the strengthening agent 7, an insulating resin of hardening type or cushioning type or the like is used. In addition, a distance L between the convex portions 6 is set to be 5 to 10 cm. The distance L is obtained by the λ/4 (quarter wavelength) conversion. Note that, λ=c/f (c=3×10⁸, f=1 GHz). Further, considering its processing method and so on, the convex portion 6 is set to have a height H equal to or larger than 0.4 mm and a diameter φ equal to or larger than 3.0 mm. As a method to process the convex portion 6, the indentation technique or the like is used.

The directly-attached filter 3 is composed of: an anti-reflection layer; an electromagnetic shielding layer; a near-infrared cut-off layer; a color correction layer for panel-emitted light; an impact absorbing layer; and the like. In the present embodiment, particularly focusing on the function of the electromagnetic shielding layer, the electrical connection between the directly-attached filter 3 and the chassis 2 is realized.

The gasket 5 is made by winding a fiber metal around a cushioning material, and the more putting pressure thereon to press it, the more the contact resistance decreases. Therefore, for the electrical connection between the directly-attached filter 3 and the chassis 2, it is desired to put pressure as much as possible to decrease the contact resistance.

Based on the foregoing, according to the plasma display device of the present embodiment, regardless of distortion of the display panel 1 and the chassis 2 caused by their size enlargement, variations in the electrical connection between the chassis 2 and the directly-attached filter 3 can be suppressed. Therefore, without putting stress on the display panel 1, variations in the electrical connection between the chassis 2 and the directly-attached filter 3 can be suppressed, thereby easily improving the ability of shielding electromagnetic wave.

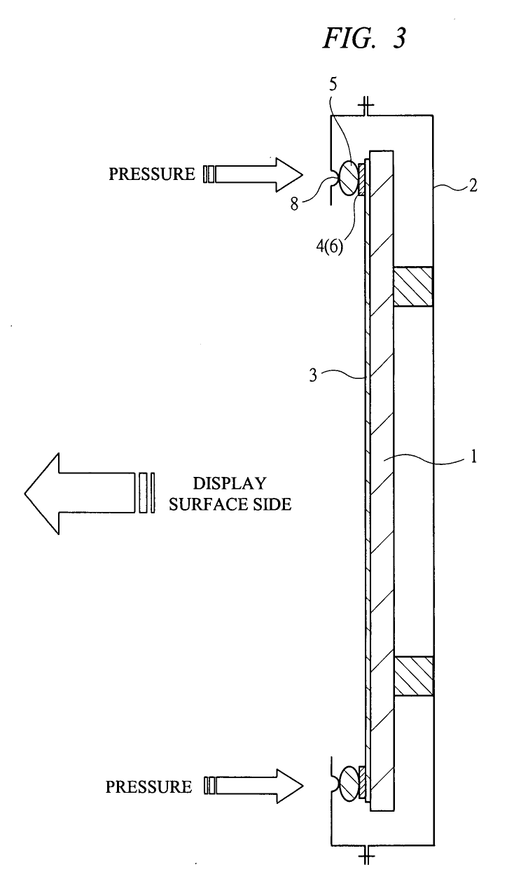

Further, in the present embodiment, as shown in FIG. 3 for example, the chassis 2 may also have convex portions 8 similar to those of the directly-attached filter 3 for the same reason. The chassis 2 in this case can be realized by forming the convex portions 8 convexing towards the directly-attached filter 3 at positions corresponding to the convex portions 6 of the directly-attached filter 3. In this case, with the convex portions 8 of the chassis 2 and the convex portions 6 of the directly-attached filter 3, variations in the electrical connection between the chassis 2 and the directly-attached filter 3 can be further suppressed.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention relates to a technique for plasma display devices, more particularly, it is applicable to a configuration of a directly-attached filter to be attached onto a display panel.

What is claimed is:

1. A filter attached to a display panel made of glass comprising:
a filter contact part to make an electrical connection between the display panel and a chassis for holding the display panel,
wherein the filter contact part has a convex portion convexing toward the chassis.

2. The filter according to claim 1,
wherein the filter contact part is placed around an outer circumference of the filter, and
the convex portions are formed all around the filter contact part.

3. The filter according to claim 1,
wherein a strengthening material is applied on a rear side of the convex portion of the filter contact part.

4. The filter according to claim 1,
wherein a distance between the convex portions is set to be 5 to 10 cm.

5. The filter according to claim 1,
wherein a height of the convex portion is set to be equal to or larger than 0.4 mm.

6. The filter according to claim 1,
wherein a diameter of the convex portion is set to be equal to or larger than 3.0 mm.

7. A plasma display device comprising:
a display panel made of glass;
a chassis holding the display device; and
a filter attached on the display panel,
wherein the filter has a filter contact part electrically connected with the chassis, and
the filter contact part has a convex portion convexing towards the chassis.

8. The plasma display device according to claim 7,
wherein the chassis has a convex portion convexing towards the filter and electrically connected with the filter, which is placed at a position corresponding to the convex portion formed on the filter contact part of the filter.
